(19) United States
(12) Patent Application Publication
(10) Pub. No.: US 2024/0151481 A1
(43) Pub. Date: May 9, 2024

(54) COOLER AND MANUFACTURING METHOD THEREOF

(71) Applicant: TOYOTA JIDOSHA KABUSHIKI KAISHA, Toyota-shi, Aichi (CN)

(72) Inventor: Shuji KAWAMURA, Toyota-shi, Aichi-ken (JP)

(73) Assignee: TOYOTA JIDOSHA KABUSHIKI KAISHA, Toyota-shi, Aichi (CN)

(21) Appl. No.: 17/773,359

(22) PCT Filed: Nov. 12, 2019
(86) PCT No.: PCT/JP2019/044437

§ 371 Date: Apr. 29, 2022

(51) Int. Cl. F28F 1/32

(52) U.S. Cl. CPC F28F 1/32; F28F 2215/04

(57) ABSTRACT

The present specification provides a technique for accelerating solidification of a liquid gasket. A cooler disclosed herein comprises a main body, a cover, a pair of first fins, and second fins. A channel through which refrigerant flows is formed in the main body. The cover is attached to the main body to close the channel with a liquid gasket. The first fins are arranged on the main body or the cover, and each of the first fins extends along a refrigerant flow direction and facing corresponding one of inner side surfaces of the channel. The second fins are arranged between the pair of first fins. A height of the first fins is smaller than a height of the second fins. The first fins having the smaller height allows larger amount of the refrigerant flowing by the liquid gasket, and thus the liquid gasket efficiently absorbs water and quickly solidified.

### TECHNICAL FIELD

Teachings disclosed herein relate to a cooler and a manufacturing method thereof, specifically to a cooler in which a liquid gasket that solidifies by absorbing water seals between a main body in which a channel through which refrigerant flows is formed and a cover covering the channel, and a manufacturing method thereof.

### BACKGROUND ART

A gasket is interposed between a main body and a cover of a cooler to prevent leakage of a refrigerant (e.g., Japanese Patent Application Publication No. 2015-65310). The gasket can be constituted of various materials, including metal, resin, natural rubber, graphite, or the like. There also are known liquid gaskets that are originally mobile but solidify after a certain period of time after applied to a sealing surface. Types of such liquid gaskets include FIPG (Formed In Place Gasket), CIPG (Cured In Place Gasket), RTVG (Room Temperature Vulcanizing Gasket), etc. A liquid gasket on which the present specification focuses is one that solidifies when absorbing water.

### SUMMARY OF INVENTION

The present specification provides a technique for accelerating solidification of a liquid gasket. A cooler disclosed in the present specification comprises a main body, a cover, a pair of first fins, and a plurality of second fins. A channel through which refrigerant flows is formed in the main body. The cover is attached to the main body to close the channel with a liquid gasket interposed between the cover and a periphery of the channel in the main body. The pair of first fins is arranged on one of the main body and the cover, and each of the first fins extends along a refrigerant flow direction and faces corresponding one of inner side surfaces of the channel. The plurality of second fins is arranged between the pair of first fins. In the cooler disclosed in the present specification, a height of the first fins is smaller than a height of the second fins. The first fins having the smaller height allows a larger amount of the refrigerant to flow between the inner side surfaces of the channel and the first fins. The liquid gasket is applied to a flat surface continuous with the inner side surfaces (flat surface facing the cover) and a part of the liquid gasket is exposed to the channel. An increased amount of the refrigerant flowing near the liquid gasket increases water absorption efficiency of the liquid gasket, thereby accelerating solidification of the liquid gasket.

In the cooler disclosed in the present specification, a gap between one of the first fins and its corresponding one of the inner side surfaces may be larger than a gap between adjacent second fins. Further, the gap between adjacent second fins may be larger than a gap between distal ends of the second fins and a channel surface facing the distal ends of the second fins. Both of these cases contribute to increasing the amount of the refrigerant flowing between the first fins and the inner side surfaces. A larger amount of the refrigerant contacts the liquid gasket exposed to the channel at ends of the inner side surfaces, thereby increasing the water absorption efficiency of the liquid gasket. Thus, the solidification of the liquid gasket is further accelerated.

A boundary between the flat surface on which the liquid gasket is applied and one of the inner side surfaces may be chamfered. The liquid gasket is exposed to the channel over a larger area at the chamfered site, increasing its contact area with the refrigerant. Thus, the solidification is further accelerated.

A refrigerant supply hole may be provided in one of the inner side surfaces at an upstream side of the channel, and in a sectional view of the main body along a plane that is perpendicular to the refrigerant flow direction and passes the refrigerant supply hole, the channel may be shallower at its portions farther away from the refrigerant supply hole. This improves balance between an amount of the refrigerant flowing along the inner side surface in which the refrigerant supply hole is provided and an amount of the refrigerant flowing along the other inner side surface.

The present specification also discloses a manufacturing method suitable for the cooler described above. According to the method, the cover is attached to the main body with the unsolidified liquid gasket interposed therebetween, and then steam is fed through the channel. The liquid gasket contacting high-temperature water (steam) reduces a solidification time.

Details and further improvements of the technique disclosed in the present specification will be described in Detailed Description below.

### BRIEF DESCRIPTION OF DRAWINGS

FIG. 1 is a plan view of a cooler according to an embodiment;

FIG. 2 is a side view of the cooler;

FIG. 3 is a cross-sectional view along a line III-III in FIG. 1;

FIG. 4 is a cross-sectional view along a line IV-IV in FIG. 1;

FIG. 5 is a diagram for explaining a manufacturing method of the cooler (assembly process); and

FIG. 6 is a diagram for explaining the manufacturing method of the cooler (solidification process).

### DESCRIPTION OF EMBODIMENTS

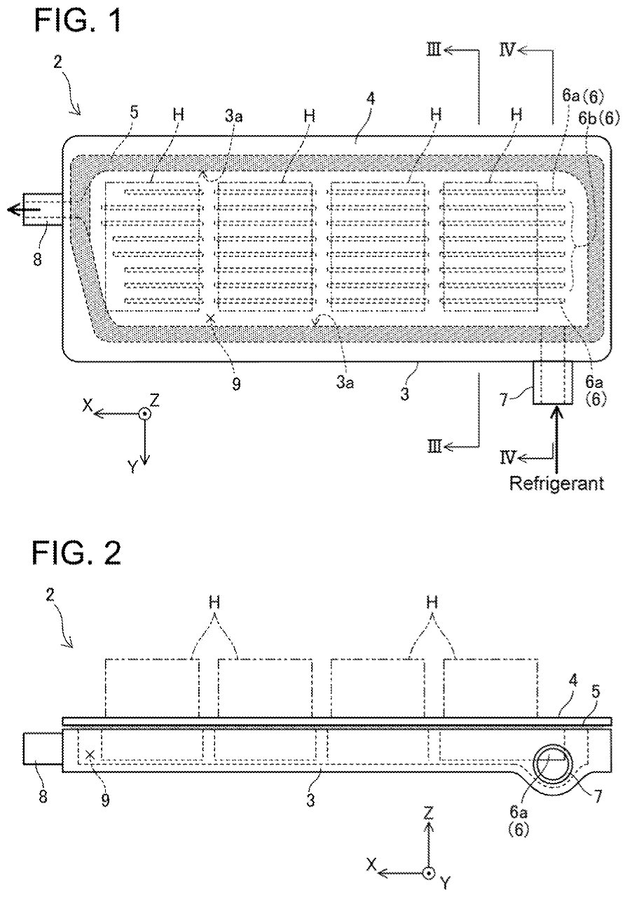

Referring to the drawings, a cooler 2 according to an embodiment is described. FIG. 1 illustrates a plan view of the cooler 2, and FIG. 2 illustrates a side view of the cooler 2.

A main body 3 of the cooler 2 has a flat, elongated cuboid shape. The main body 3 is hollow, and a refrigerant flows through the hollow space. A refrigerant supply hole 7 is provided in the main body 3 on the right side of the drawing, and a refrigerant discharge hole 8 is provided on the left side of the drawing.

The main body 3 is elongated along an X-direction in the coordinate system in the drawings, and refrigerant flows in the longitudinal direction of the main body 3 (in the X-direction). In other words, the X-direction in the coordinate system in the drawings corresponds to a refrigerant flow direction. The hollow space within the main body 3 is termed a channel 9. The refrigerant supply hole 7 is provided in an inner side surface 3a of the channel 9. The inner side surface 3a refers to a narrower inner surface among inner surfaces of the flat channel 9 along the refrigerant flow direction. The refrigerant is liquid, and may typically be water. For the sake of descriptive convenience, +Z-direction in the coordinate system in the drawings is defined as “upward”.

The main body 3 is open upward, and a cover 4 is attached to the opening. As viewed in a normal direction of the cover 4, a gasket 5 is arranged to surround the channel 9, and the cover 4 is attached to the main body 3 with the gasket 5 interposed therebetween. The cover 4 is attached to the main body 3 with a bolt, although this is not illustrated. When the cover 4 is attached, the channel 9 is sealed by the gasket 5. That is, the cover 4 is attached to the main body 3 to close the channel 9.

The gasket 5 is a liquid gasket and originally mobile. The liquid gasket is applied to a flat surface around the channel 9 of the main body 3 and is also applied to the corresponding area of the cover 4, and then the cover 4 is put together with the main body 3 and fixed with a bolt. After a predetermined period of time, the liquid gasket solidifies by absorbing water. Once the liquid gasket has solidified, the channel 9 between the cover 4 and the main body 3 is completely sealed. However, the liquid gasket takes time to solidify. The cooler 2 according to the embodiment includes a structure that accelerates the solidification of the liquid gasket.

As described, in the completed cooler 2, the liquid gasket has solidified and become the gasket 5. However, in the following description, the gasket 5 is referred to as the liquid gasket 5 to aid understanding. To aid understanding, the liquid gasket 5 is depicted in gray in FIG. 1 (and the subsequent drawings).

The flat cooler 2 allows attachment of a heat emitting source H to be cooled to the cover 4. The heat emitting source H is, for example, a reactor. In FIGS. 1 and 2, a plurality of heat emitting sources H is indicated by imaginary lines. The cooler 2 is used, for example, in a power converter including a plurality of reactors. The cooler 2 is disposed within a housing of the power converter and the plurality of reactors (heat emitting sources H) is attached to the cover 4.

The cooler 2 comprises a plurality of fins 6 within the main body 3. The fins 6 are attached to a rear surface of the cover 4 (a surface thereof facing the channel 9) to which the heat emitting sources H are attached. The fins 6 extend in the refrigerant flow direction (i.e., in the X-direction). For the sake of descriptive convenience, fins that face a pair of inner side surfaces 3a of the channel 9 are referred to as first fins (a pair of first fins 6a), and a plurality of fins between the pair of first fins 6a is referred to as second fins 6b. In other words, the first fins 6a are the fins closest to the respective inner side surfaces 3a. The first fins 6a and the second fins 6b are collectively referred to as the fins 6 where they do not need to be distinguished from each other.

The fins 6 are provided to efficiently dissipate the heat of the heat emitting sources H transferred through the cover 4 to the refrigerant. That is, the fins 6 improve cooling performance for the heat emitting sources H. In FIG. 1 (and the subsequent drawings), the fins 6 are flat plates, however, they may have a wavy shape along the refrigerant flow direction.

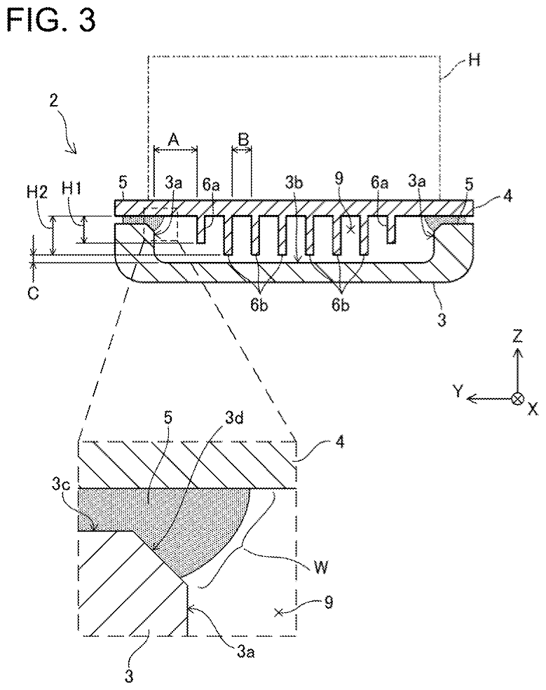

FIG. 3 illustrates across-sectional view along a line III-III in FIG. 1. FIG. 3 also depicts the heat emitting source H by an imaginary line. The lower diagram in FIG. 3 is an enlarged view of the area enclosed by a broken line in the upper diagram. As illustrated in the lower diagram in FIG. 3, a chamfer 3d is applied to a boundary between the inner side surface 3a of the main body 3 and a flat surface 3c (a flat surface facing the cover 4) to which the liquid gasket 5 is applied. The liquid gasket 5 extend across a range of width W along the chamfer 3d. The application of the chamfer 3d increases an area of the liquid gasket 5 exposed to the channel 9. That is, the liquid gasket 5 contacts the refrigerant over a larger area. This helps the liquid gasket 5 absorb a larger amount of water, thereby accelerating the solidification of the liquid gasket 5. The flat surface 3c to which the liquid gasket 5 is applied may be referred to as a main body-side sealing surface.

A height H1 of the first fins 6a facing the inner side surfaces 3a is smaller than a height H2 of the second fins 6b. This structural feature contributes to increasing an amount of the refrigerant flowing along the inner side surfaces 3a. The increased amount of the refrigerant flowing along the inner side surfaces 3a facilitates water absorption of the liquid gasket 5. Thus, the structural feature also accelerates the solidification of the liquid gasket 5.

A gap A between each inner side surface 3a and its corresponding first fin 6a is larger than a gap B between adjacent second fins 6b. This structural feature also contributes to increasing an amount of the refrigerant flowing along the inner side surface 3a. This structural feature also accelerates the solidification of the liquid gasket 5.

The gap B between adjacent second fins 6b is larger than a gap C between distal ends of the second fins 6b and a bottom surface 3b of the main body 3. Conversely, the gap C between the distal ends of the second fins 6b and the bottom surface 3b of the main body 3 is smaller than the gap B between adjacent second fins 6b. This structural feature also contributes to increasing the amount of the refrigerant flowing along the inner side surfaces 3a of the channel 9. This structural feature also accelerates the solidification of the liquid gasket 5.

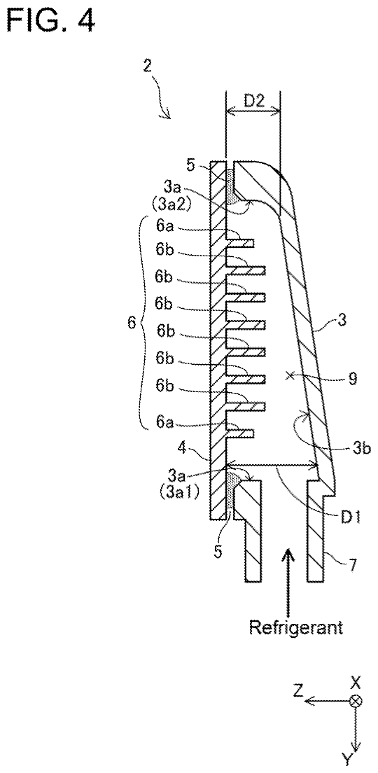

FIG. 4 illustrates a cross-sectional view along a line IV-IV in FIG. 1. FIG. 4 illustrates a cross section of the cooler 2 along a plane that is perpendicular to the refrigerant flow direction (X-direction) and passes the refrigerant supply hole 7. As described, the refrigerant supply hole 7 is provided in the inner side surface 3a of the channel 9. A depth D1 of the channel 9 near the refrigerant supply hole 7 is larger than a depth D2 of the channel 9 distant from the refrigerant supply hole 7. The bottom surface 3b of the channel 9 comes closer to the cover 4 at its portions farther away from the refrigeration supply hole 7. In other words, the channel 9 is shallower at its portions farther away from the refrigerant hole 7. This structural feature improves balance between an amount of the refrigerant flowing along the inner side surface 3a(3a1) in which the refrigerant supply hole 7 is provided and an amount of the refrigerant flowing along the inner side surface 3a(3a2) farther away from the refrigerant supply hole 7.

As described, in the cooler 2 according to the embodiment, the channel 9 is sealed by the liquid gasket 5, and the cooler 2 includes some structural features that accelerate the solidification of the liquid gasket 5.

Next, a manufacturing method of the cooler 2 is described.

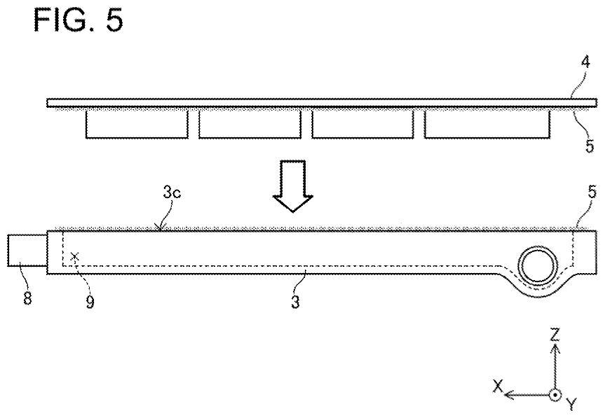

(Assembly Process) Referring to FIG. 5, an assembly process is described. The liquid gasket 5 is applied to the flat surface around the channel 9 of the main body 3, the liquid gasket 5 is applied also to the corresponding area of the cover 4 (area facing the liquid gasket 5 applied to the main body 3), and then the cover 4 is attached to the main body 3. The liquid gasket 5 starts to solidify when applied, however, it takes some time to completely solidify.

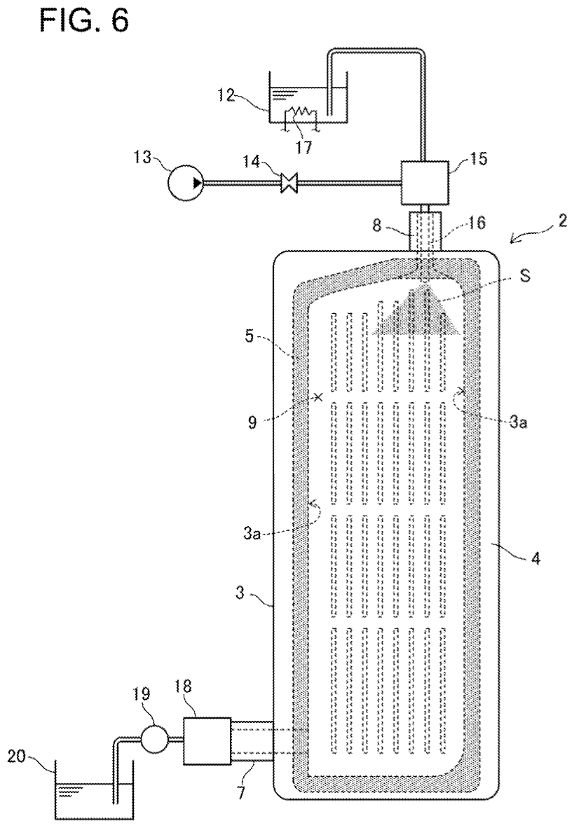

(Solidification Process) Referring to FIG. 6, a solidification process is described. In the solidification process, steam S is fed through the channel 9. In the example of FIG. 6, a fluid coupler 15 is attached to the refrigerant discharge hole 8. A spray nozzle 16 extends from the fluid coupler 15 into the channel 9. An air pump 13 is connected to the fluid coupler 15 via a regulation valve 14 and a hot water tank 12 is also connected to the fluid coupler 15. A heater 17 is provided in the hot water tank 12 to heat water in the hot water tank 12.

When the air pump 13 pumps air with a predetermined pressure to the fluid coupler 15, hot water is suctioned from the hot water tank 12 and the steam S is sprayed from the spray nozzle 16 into the channel 9. The high-temperature steam accelerates the solidification of the liquid gasket 5.

A drain coupler 18 is attached to the refrigerant supply hole 7 of the cooler 2. A humidity sensor 19 and a drain tank 20 are attached to the drain coupler 18. The hot water sprayed into the channel 9 is collected in the drain tank 20 through the drain coupler 18. The humidity of the steam S is measured by the humidity sensor 19, and the temperature of the hot water and a discharge pressure of the steam from the nozzle are controlled such that the humidity is maintained at an appropriate level.

The discharge of the steam S into the channel 9 accelerates the solidification of the liquid gasket 5.

After the steam has been sprayed, the refrigerant is fed through the channel 9 to ensure the sealing performance of the liquid gasket 5. At this time, the structural features of the cooler 2 exhibit the effects, and thus the solidification of the liquid gasket 5 is also accelerated by the refrigerant during the test.

Some features related to the technique described in the embodiment will be listed. The liquid gasket 5 starts to solidify when absorbing water. A typical liquid gasket that solidifies by water absorption is FIPG (Formed In Place Gasket).

In the cooler 2 according to the embodiment, the fins 6 are disposed on the rear surface of the cover 4. The fins 6 may be disposed on the bottom surface 3b of the main body 3. In this case, the heat emitting sources are attached to the main body 3.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present specification or drawings provide technical utility either independently or through various combinations. The present disclosure is not limited to the combinations described at the time the claims are filed. Further, the purpose of the examples illustrated by the present specification or drawings is to satisfy multiple objectives simultaneously, and satisfying any one of those objectives gives technical utility to the present disclosure.

What is claimed is:

1. A cooler comprising:
a main body in which a channel through which refrigerant flows is formed, the channel including a pair of inner side surfaces extending along a refrigerant flow direction;
a cover attached to the main body to close the channel;
a liquid gasket arranged around the channel of the main body between the cover and the main body, the liquid gasket solidifying by absorbing water;
a pair of first fins arranged on one of the main body and the cover, each of the first fins extending along the refrigerant flow direction and facing corresponding one of the inner side surfaces; and
a plurality of second fins arranged between the pair of first fins,
wherein
a height of the first fins is smaller than a height of the second fins.

2. The cooler of claim 1, wherein a gap between one of the first fins and its corresponding one of the inner side surfaces is larger than a gap between adjacent second fins.

3. The cooler of claim 2, wherein the gap between adjacent second fins is larger than a gap between distal ends of the second fins and a channel surface facing the distal ends of the second fins.

4. The cooler of claim 1, wherein a boundary between a flat surface of the main body on which the liquid gasket is applied and one of the inner side surfaces is chamfered.

5. The cooler of claim 1, wherein
a refrigerant supply hole is provided in one of the inner side surfaces at an upstream side of the refrigerant flow direction, and
in a cross-sectional view of the main body along a plane that is perpendicular to the refrigerant flow direction and passes the refrigerant supply hole, the channel is shallower at its portions farther away from the refrigerant supply hole.

6. A manufacturing method of the cooler of claim 1, comprising:
applying the liquid gasket before it is solidified on one of the main body and the cover;
attaching the cover to the main body; and
feeding steam through the channel after the cover has been attached to the main body.
